(19) United States
(12) Patent Application Publication
(10) Pub. No.: US 2024/0120913 A1
(43) Pub. Date: Apr. 11, 2024

(54) GATE DRIVER

(71) Applicant: Infineon Technologies Austria AG, Villach (AT)

(72) Inventors: Christian LOCATELLI, Pavia (IT); Diego RAFFO, Redondo Beach, CA (US); Zhou Jonah CHEN, Seal Beach, CA (US); Weidong CHU, San Pedro, CA (US)

(21) Appl. No.: 17/960,363

(22) Filed: Oct. 5, 2022

(51) Int. Cl. H03K 17/16

(52) U.S. Cl. CPC H03K 17/165; H03K 2217/0027

(57) ABSTRACT

A gate driver comprises an input terminal, an output terminal, and first logic configured to generate an output drive signal at the output terminal corresponding to an input drive signal received at the input terminal. A blanking unit is configured to connect a current sense terminal of the gate driver to a reference supply terminal responsive to a low value of the output drive signal and disconnect the current sense terminal from the reference supply terminal after a predetermined delay period responsive to a high value of the output drive signal.

### TECHNICAL FIELD

The present disclosure relates generally to power transistors, and, more particularly, to providing blanking on a current sense terminal of a gate driver.

### BACKGROUND

A power semiconductor device comprises a semiconductor structure configured to conduct a load current along a load current path between two load terminal structures of the device. The load current path may be controlled by a control electrode, sometimes referred to as a gate electrode. A gate diver provides a drive signal for the control electrode to set the power semiconductor device in one of a conducting state or a blocking state. A current sense terminal of the gate driver facilitates monitoring of current flowing through the power transistor.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, a gate driver comprises an input terminal, an output terminal, first logic configured to generate an output drive signal at the output terminal corresponding to an input drive signal received at the input terminal, a current sensing terminal, a reference supply terminal, and a blanking unit configured to connect the current sense terminal to the reference supply terminal responsive to a low value of the output drive signal and disconnect the current sense terminal from the reference supply terminal after a predetermined delay period responsive to a high value of the output drive signal.

According to some embodiments, a system for generating a gate driver signal comprises means for receiving an input drive signal at an input terminal of a gate driver, means for generating an output drive signal at an output terminal of the gate driver corresponding to the input drive signal, means for connecting a current sense terminal of the gate driver to a reference supply terminal of the gate driver responsive to a low value of the output drive signal, and means for disconnecting the current sense terminal from the reference supply terminal after a predetermined delay period responsive to a high value of the output drive signal.

According to some embodiments, a method for generating a gate driver signal comprises receiving an input drive signal at an input terminal of a gate driver, generating an output drive signal at an output terminal of the gate driver corresponding to the input drive signal, connecting a current sense terminal of the gate driver to a reference supply terminal of the gate driver responsive to a low value of the output drive signal, and disconnecting the current sense terminal from the reference supply terminal after a predetermined delay period responsive to a high value of the output drive signal.

According to some embodiments, a gate driver comprises an input terminal, an output terminal, a level shift up unit, control logic configured to generate a set signal in the level shift up unit responsive to an input drive signal having a high value and to generate a reset signal in the level shift up unit responsive to the input drive signal having a low value, a flip flop coupled to the level shift up unit and configured to generate a pre-drive signal based on value of the set signal and the reset signal, a driver connected to the flip flop and configured to generate an output drive signal at the output terminal based on the pre-drive signal, a current sensing terminal, a reference supply terminal, a blanking transistor coupled across the current sensing terminal and the reference supply terminal, and a blanking control unit connected to a gate of the blanking transistor and configured to turn on the blanking transistor responsive to a low value of the pre-drive signal and to turn off the blanking transistor after a predetermined delay period responsive to a high value of the pre-drive signal.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a schematic diagram of a gate driver, according to some embodiments.

FIG. 2 is a diagram of a power transistor circuit, according to some embodiments.

FIGS. 3 and 4 are timing diagrams for a gate driver during short circuit events, according to some embodiments.

FIG. 5 illustrates a method of generating a gate driver signal, according to some embodiments.

FIG. 6 illustrates an exemplary computer-readable medium, according to some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

Equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually exchangeable.

In this regard, directional terminology, such as “top”, “bottom”, “below”, “above”, “front”, “behind”, “back”, “leading”, “trailing”, etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope defined by the claims. The following detailed description, therefore, is not to be taken in a limiting sense.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In embodiments described herein or shown in the drawings, any direct electrical connection or coupling, i.e., any connection or coupling without additional intervening elements, may also be implemented by an indirect connection or coupling, i.e., a connection or coupling with one or more additional intervening elements, or vice versa, as long as the general purpose of the connection or coupling, for example, to transmit a certain kind of signal or to transmit a certain kind of information, is essentially maintained. Features from different embodiments may be combined to form further embodiments. For example, variations or modifications described with respect to one of the embodiments may also be applicable to other embodiments unless noted to the contrary.

The term “substantially” may be used herein to account for small manufacturing tolerances (e.g., within 5%) that are deemed acceptable in the industry without departing from the aspects of the embodiments described herein.

A gate of a transistor, such as a power transistor, is driven by an output drive signal of a gate driver. The gate driver includes a current sense terminal and a fault detection circuit to facilitate current monitoring in the power transistor. A blanking unit connects the current sense terminal to a reference terminal of the gate driver to reset sensing circuitry of the external power transistor circuit between assertions of the output drive signal by the gate driver. In some embodiments, the blanking unit connects the current sense terminal to the reference supply terminal by closing a blanking transistor when the output drive signal is low, thereby resetting the external current sensing circuitry. Responsive to the output drive signal going high, the blanking unit opens the blanking transistor to facilitate current sensing and fault detection.

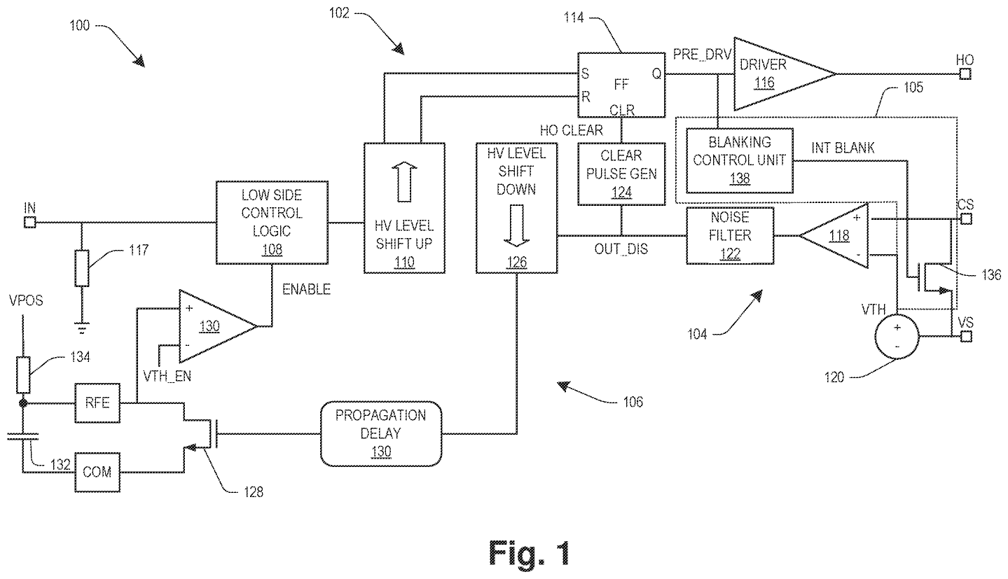

Referring to FIG. 1 a schematic diagram of a gate driver 100 is provided, according to some embodiments. The gate driver 100 comprises an input (IN) terminal, gate driving logic 102 connected to an output (HO) terminal, fault detection logic 104 coupled to a current sense (CS) terminal and a reference supply (VS) terminal, a blanking unit 105, and fault indication logic 106.

In some embodiments, the gate driving logic 102 comprises low-side control logic 108, a high voltage (HV) level shift up unit 110, a flip flop 114, and a driver 116. An input resistor 117 is connected to the IN terminal. The low-side control logic 108 receives an input drive signal and controls the HV level shift up unit 110 to generate a set signal that is high responsive to the input drive signal being high and to generate a reset signal that is high responsive to the input drive signal being low. The set and reset signals are provided to the flip flop 114 to control the output, Q, of the flip flop 114. The output of the flip flop 114 is a pre-drive (PRE_DRV) signal. In some embodiments, the flip flop 114 is an asynchronous device. The driver 116 receives the PRE_DRV signal and generate the output drive signal at the HO terminal. Other structures and configurations of the gate driving logic 102 are within the scope of the present disclosure.

In some embodiments, the fault detection logic 104 facilitates current monitoring fault detection in the power transistor connected to the gate driver 100 to detect a desaturation fault in the power transistor. The fault detection logic 104 comprises a comparator 118 connected to the CS terminal and a threshold voltage (VTH) source 120 referenced to a reference voltage (VS) of the gate driver 100. The comparator 118 outputs a logic signal having a “high” value responsive to the CS voltage exceeding VTH. A noise filter 122 is coupled to the comparator 118 to reduce noise in the logic signal. The output of the noise filter 122 is an output disable signal, OUT_DIS, that indicates that a fault condition exists with the power transistor and that the output drive signal should be removed. The noise filter 122 is connected to a clear pulse generator 124. In some embodiments, the clear pulse generator 124 generates a pulse, HO_CLEAR, responsive to an assertion of the OUT_DIS signal. The HO_CLEAR pulse may be delayed by a predetermined time period after assertion of the OUT_DIS signal. The clear pulse is provided to a CLR input of the flip flop 114 to reset the flip flop 114, causing the PRE_DRV signal to go low and turn off the driver 116. Other structures and configurations of the fault detection logic 104 are within the scope of the present disclosure.

In some embodiments, the fault indication logic 106 comprises a HV level shift down unit 126 that receives the OUT_DIS signal and controls a fault indication transistor 128. The HV level shift down unit 126 includes an intrinsic delay represented by a propagation delay 130 shown in phantom. In some embodiments. The HV level shift down unit 126 enables the fault indication transistor 128 responsive to the OUT_DIS signal being high, allowing voltage on a fault indication capacitor 132 to decay, which may be detected by monitoring a voltage across a fault report terminal (RFE) terminal and a low side voltage domain terminal (COM). A fault indication signal across the RFE terminal and the COM terminal may be monitored by an external device, such as a controller or a microprocessor. A voltage source, VPOS, is coupled to the fault indication capacitor 132 through a resistor 134 to charge the fault indication capacitor 132 when a fault is not present. Other structures and configurations of the fault indication logic 106 are within the scope of the present disclosure.

In some embodiments, the blanking unit 105 comprises a blanking transistor 136 connected across the CS terminal and the VS terminal and a blanking control unit 138 connected to a gate of the blanking transistor 136. Responsive to the PRE_DRV signal (representative of the output drive signal) being low, the blanking control unit 138 sends a logic high signal to close the blanking transistor 136 and short the CS terminal to the VS terminal, allowing blanking of external fault detection circuitry associated with the power transistor. Responsive to the PRE_DRV signal being high, the blanking control unit 138 sends a logic low signal to open the blanking transistor 136 and open the connection between the CS terminal and the VS terminal to facilitate current sensing fault detection. In some embodiments, the blanking control unit 138 generates an internal blanking signal, INT BLANK, a predetermined time period after assertion of the PRE_DRV signal. The INT BLANK signal maybe a pulse with a predetermined on time period.

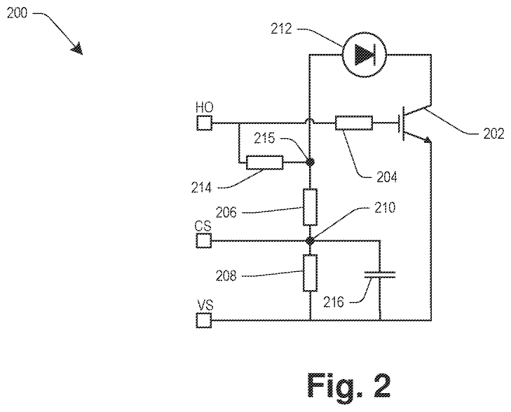

Referring to FIG. 2, a diagram of a power transistor circuit 200 is provided, according to some embodiments. In some embodiments, the power transistor circuit 200 comprises a power transistor 202 having a gate terminal connected to the HO terminal through a gate resistor 204. Resistors 206, 208 are connected at a node 210. A diode 212 is coupled in series across the power transistor 202. A resistor 214 is connected between the HO terminal and the resistor 206. Current sensing is provided by the resistors 206, 208, 214, and the diode 212. The resistors 206, 208, and 214 form a voltage divider at the node 210 connected to the CS terminal. The voltage at the node 210 is representative of current passing through the power transistor 202. In normal operation, when the power transistor 202 turns on, the voltage drop between the collector and the emitter of the power transistor 202 is low, which clamps the voltage at the node 215 between the resistor 214 and the resistor 206 by the diode 212, the voltage at the node 210 is lower than an over current threshold, so no current protection is implemented. However, in a short circuit condition of the power transistor 202, the voltage drop between the collector and the emitter is high when the power transistor 202 turns on, so the voltage at the node 210 is sufficiently high to trigger over current protection.

A blanking capacitor 216 is connected across the CS terminal and the VS terminal and charges based on the voltage at the node 210 when the power transistor 202 is in an “ON” state. When the power transistor 202 is in an “OFF” state, the voltage in the blanking capacitor 216 decays. However, since the voltage at the VS terminal may be floating, the decay at the blanking capacitor 216 may be incomplete without the intervention from the blanking unit 105. Incomplete decay of the voltage in the blanking capacitor 216 may result in integration of the error signal over time and errant fault indication. The blanking unit 105 shorts the CS terminal to the VS terminal to cause complete decay in the blanking capacitor 216 between assertions of the HO signal. Other structures and configurations of the power transistor circuit 200 are within the scope of the present disclosure.

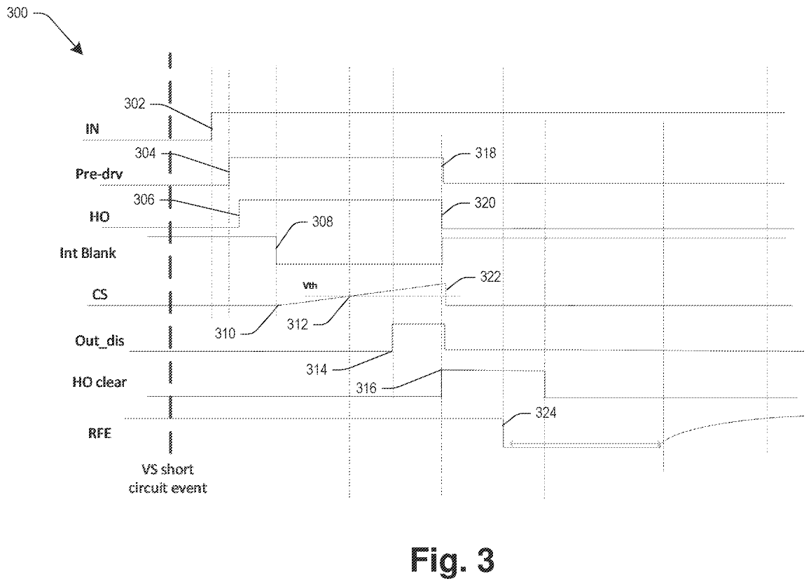

Referring to FIG. 3, a timing diagram 300 illustrating a turn on event in the presence of a short circuit fault in the power transistor 202, according to some embodiments. The signal at the IN terminal is asserted at 302. The PRE_DRV signal is asserted at 304 after a propagation time delay associated with the HV level shift up unit 110 and the flip flop 114. The HO signal is asserted at 306 after a time delay associated with the driver 116.

Prior to assertion of the PRE_DRV signal, the blanking control unit 138 generates the INT BLANK signal at a logic high level to close the blanking transistor 136 and cause decay of the signal at the CS terminal, i.e., decay on the blanking capacitor 216 of the power transistor circuit 200. The blanking control unit 138 generates a blanking pulse 308 after a predetermined time period from the assertion of the PRE_DRV signal (representative of the HO signal) to open the blanking transistor 136 and allow the blanking capacitor 216 to charge at 310 based on the current in the power transistor 202 resulting from the short circuit (seen as an increase in the voltage as the CS terminal).

When the voltage at the CS terminal reaches VTH at 312, the comparator 118 generates a high output, which passes through the noise filter 122 to generate the OUT_DIS signal at 314. The clear pulse generator 124 generates the HO clear pulse at 316 to clear the flip flop 114, resulting in PRE_DRV being deasserted at 318 and the signal at the HO terminal going low at 320. The PRE_DRV signal being deasserted at 318 causes the blanking control unit 138 to close the blanking transistor 136 and cause decay of the voltage at the CS terminal at 322. The signal at the RFE terminal goes low at 324 after the propagation delay 130 associated with the HV level shift low unit 126 going low based on the OUT_DIS signal and closing the fault indication transistor 128.

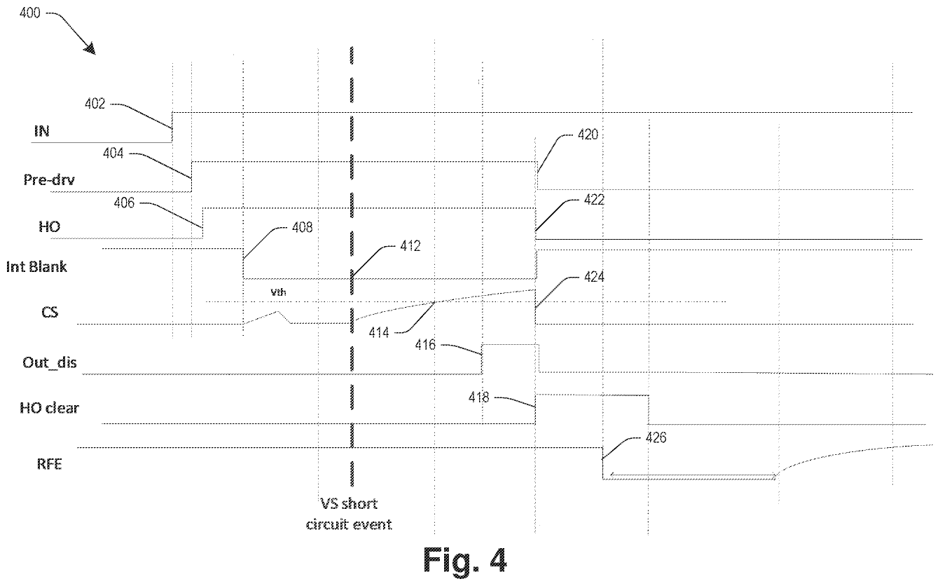

Referring to FIG. 4, a timing diagram 400 illustrating a short circuit event occurring while the HO signal was previously asserted to turn on the power transistor 202, according to some embodiments. The signal at the IN terminal is asserted at 402. The PRE_DRV signal is asserted at 404 after a propagation time delay associated with the HV level shift up unit 110 and the flip flop 114. The HO signal is asserted after a time delay associated with the driver 116.

Prior to assertion of the PRE_DRV signal, the blanking control unit 138 generates the INT BLANK signal at a logic high level to close the blanking transistor 136 and cause decay of the signal at the CS terminal, i.e., decay on the blanking capacitor 216 of the power transistor circuit 200. The blanking control unit 138 generates a blanking pulse 408 after a predetermined time period from the assertion of the PRE_DRV signal (representative of the HO signal) to open the blanking transistor 136 and allow the blanking capacitor 216 to charge at 408 based on the current in the power transistor 202. Since no fault is present, the voltage at the CS terminal does not exceed VTH.

A short circuit occurs at 412, causing the blanking capacitor 216 to charge based on the current in the power transistor 202 resulting from the short circuit (seen as an increase in the voltage as the CS terminal). When the voltage at the CS terminal reaches VTH at 414, the comparator 118 generates a high output, which passes through the noise filter 122 to generate the OUT_DIS signal at 416. The clear pulse generator 124 generates the HO clear pulse at 418 to clear the flip flop 114, resulting in PRE_DRV being deasserted at 420 and the signal at the HO terminal going low at 422. The PRE_DRV signal being deasserted at 420 causes the blanking control unit 138 to close the blanking transistor 136 and cause decay of the voltage at the CS terminal at 424. The signal at the RFE terminal goes low at 426 after the propagation delay 130 associated with the HV level shift down unit 126 going high based on the OUT_DIS signal and turning on the fault indication transistor 128.

Connecting the CS terminal to the VS terminal by enabling the blanking transistor 136 between assertions of the HO signal allows the blanking capacitor 216 to reset, thereby avoiding errant fault detection.

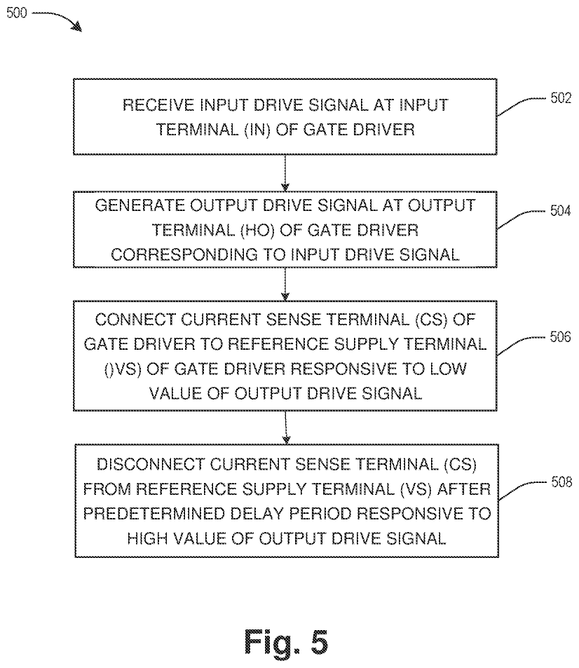

Referring to FIG. 5, a flow diagram of a method 500 for generating a gate driver signal is provided, according to some embodiments. At 502, an input drive signal is received at an input terminal (IN) of a gate driver 100. At 504, an output drive signal is generated at an output terminal (HO) of the gate driver 100 corresponding to the input drive signal. At 506, a current sense terminal (CS) of the gate driver 100 is connected to a reference supply terminal (VS) of the gate driver 100 responsive to a low value of the output drive signal. At 508, the current sense terminal (CS) is disconnected from the reference supply terminal (VS) after a predetermined delay period responsive to a high value of the output drive signal.

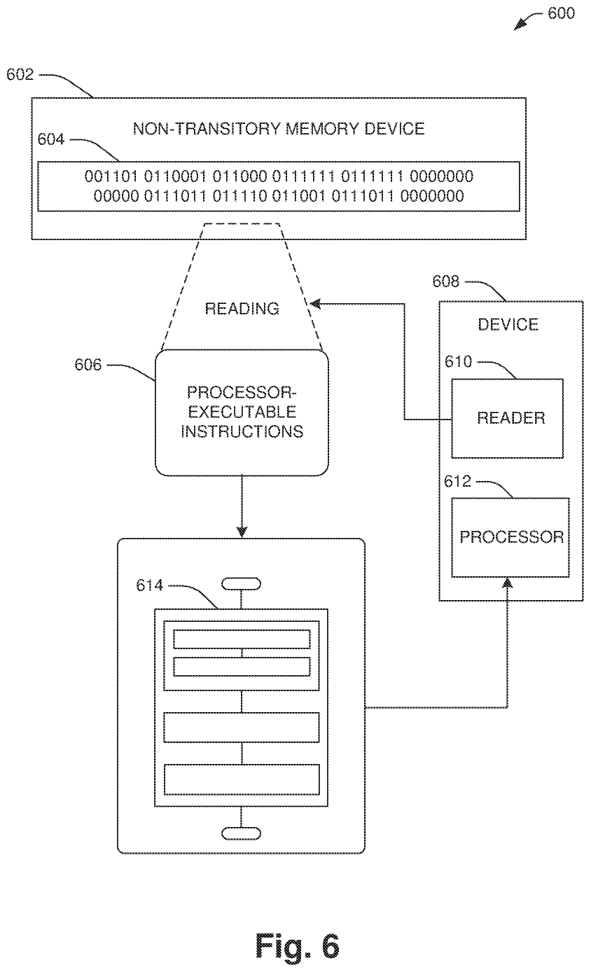

FIG. 6 illustrates an exemplary embodiment 600 of a computer-readable medium 602, according to some embodiments. One or more embodiments involve a computer-readable medium comprising processor-executable instructions configured to implement one or more of the techniques presented herein. The embodiment 600 comprises a non-transitory computer-readable medium 602 (e.g., a CD-R, DVD-R, flash drive, a platter of a hard disk drive, etc.), on which is encoded computer-readable data 604. This computer-readable data 604 in turn comprises a set of processor-executable computer instructions 606 that, when executed by a computing device 608 including a reader 610 for reading the processor-executable computer instructions 606 and a processor 612 for executing the processor-executable computer instructions 606, are configured to facilitate operations according to one or more of the principles set forth herein. In some embodiments, the processor-executable computer instructions 606, when executed, are configured to facilitate performance of a method 614, such as at least some of the aforementioned method(s). In some embodiments, the processor-executable computer instructions 606, when executed, are configured to facilitate implementation of a system, such as at least some of the one or more aforementioned system(s). Many such computer-readable media may be devised by those of ordinary skill in the art that are configured to operate in accordance with the techniques presented herein.

The term “computer readable media” may include communication media. Communication media typically embodies computer readable instructions or other data in a “modulated data signal” such as a carrier wafer or other transport mechanism and includes any information delivery media. The term “modulated data signal” may include a signal that has one or more of its characteristics set or changed in such a manner as to encode information in the signal.

According to some embodiments, a gate driver comprises an input terminal, an output terminal, first logic configured to generate an output drive signal at the output terminal corresponding to an input drive signal received at the input terminal, a current sensing terminal, a reference supply terminal, and a blanking unit configured to connect the current sense terminal to the reference supply terminal responsive to a low value of the output drive signal and disconnect the current sense terminal from the reference supply terminal after a predetermined delay period responsive to a high value of the output drive signal.

According to some embodiments, the blanking unit comprises a blanking transistor connected across the current sense terminal and the reference supply terminal, and a blanking control unit connected to a gate of the blanking transistor and configured to turn on the blanking transistor responsive to a low value of the output drive signal and to turn off the blanking transistor after a predetermined delay period responsive to a high value of the output drive signal.

According to some embodiments, the first logic comprises control logic connect to the input terminal to receive the input drive signal, a level shift up unit connected to the control logic and controlled by the control logic to assert a set signal responsive to the input drive signal having a high value and to assert a reset signal responsive to the input drive signal having a low value, a flip flop coupled to the level shift up unit and configured to generate a pre-drive signal based on value of the set signal and the reset signal, and a driver connected to the flip flop and configured to generate the output drive signal based on the pre-drive signal.

According to some embodiments, the gate driver comprises second logic connected to the current sense terminal configured to generate a clear signal at a clear terminal of the flip flop responsive to a voltage at the current sense terminal exceeding a threshold voltage.

According to some embodiments, the second logic comprises a comparator connected to the current sense terminal and a voltage source corresponding to the threshold voltage and configured to generate the clear signal responsive to a voltage on the current sense terminal exceeding the threshold voltage, a noise filter connected to an output of the comparator, and a pulse generator connected to the noise filter and the clear terminal of the flip flop and configured to generate a clear pulse based on the clear signal.

According to some embodiments, the gate driver comprises second logic connected to the current sense terminal configured to generate a disable signal to deassert the output drive signal responsive to a voltage at the current sense terminal exceeding a threshold voltage.

According to some embodiments, the gate driver comprises a level shift down unit connected to the second logic to receive the disable signal.

According to some embodiments, a system for generating a gate driver signal comprises means for receiving an input drive signal at an input terminal of a gate driver, means for generating an output drive signal at an output terminal of the gate driver corresponding to the input drive signal, means for connecting a current sense terminal of the gate driver to a reference supply terminal of the gate driver responsive to a low value of the output drive signal, and means for disconnecting the current sense terminal from the reference supply terminal after a predetermined delay period responsive to a high value of the output drive signal.

According to some embodiments, a method for generating a gate driver signal comprises receiving an input drive signal at an input terminal of a gate driver, generating an output drive signal at an output terminal of the gate driver corresponding to the input drive signal, connecting a current sense terminal of the gate driver to a reference supply terminal of the gate driver responsive to a low value of the output drive signal, and disconnecting the current sense terminal from the reference supply terminal after a predetermined delay period responsive to a high value of the output drive signal.

According to some embodiments, connecting the current sense terminal of the gate driver to the reference supply terminal of the gate driver comprises enabling a blanking transistor coupled across the current sensing terminal and the reference supply terminal, and disconnecting the current sense terminal from the reference supply terminal comprises disabling the blanking transistor.

According to some embodiments, generating the output drive signal comprises controlling a level shift up unit connected to assert a set signal responsive to the input drive signal having a high value and to assert a reset signal responsive to the input drive signal having a low value, generating a pre-drive signal based on value of the set signal and the reset signal, and generating the output drive signal based on the pre-drive signal.

According to some embodiments, the method comprises generating a clear signal responsive to a voltage at the current sense terminal exceeding a threshold voltage.

According to some embodiments, generating the clear signal comprises comparing the threshold voltage to a voltage on the current sense terminal to generate the clear signal, filtering noise in the clear signal, and generating a clear pulse based on the clear signal.

According to some embodiments, the method comprises generating a disable signal to deassert the output drive signal responsive to a voltage at the current sense terminal exceeding a threshold voltage.

According to some embodiments, the method comprises shifting a voltage level of the disable signal from a first voltage level to a second voltage level less than the first voltage level.

According to some embodiments, a gate driver comprises an input terminal, an output terminal, a level shift up unit, control logic configured to generate a set signal in the level shift up unit responsive to an input drive signal having a high value and to generate a reset signal in the level shift up unit responsive to the input drive signal having a low value, a flip flop coupled to the level shift up unit and configured to generate a pre-drive signal based on value of the set signal and the reset signal, a driver connected to the flip flop and configured to generate an output drive signal at the output terminal based on the pre-drive signal, a current sensing terminal, a reference supply terminal, a blanking transistor coupled across the current sensing terminal and the reference supply terminal, and a blanking control unit connected to a gate of the blanking transistor and configured to turn on the blanking transistor responsive to a low value of the pre-drive signal and to turn off the blanking transistor after a predetermined delay period responsive to a high value of the pre-drive signal.

According to some embodiments, the gate driver comprises fault detection logic connected to the current sense terminal configured to generate a clear signal at a clear terminal of the flip flop responsive to a voltage at the current sense terminal exceeding a threshold voltage.

According to some embodiments, the fault detection logic comprises a comparator connected to the current sense terminal and a voltage source corresponding to the threshold voltage and configured to generate the clear signal responsive to a voltage on the current sense terminal exceeding the threshold voltage, a noise filter connected to an output of the comparator, and a pulse generator connected to the noise filter and the clear terminal of the flip flop and configured to generate a clear pulse based on the clear signal.

According to some embodiments, the gate driver comprises fault detection logic connected to the current sense terminal configured to generate a disable signal to deassert the output drive signal responsive to a voltage at the current sense terminal exceeding a threshold voltage.

According to some embodiments, the gate driver comprises a level shift down unit connected to the fault detection logic to receive the disable signal.

According to some embodiments, the gate driver comprises a first fault indication terminal, a second fault indication terminal, a fault indication transistor coupled across the first fault indication terminal and the second fault indication terminal and having a gate terminal connected to the level shift down unit, and a capacitor coupled across the first fault indication terminal and the second fault indication terminal.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

1. A gate driver, comprising:
an input terminal;
an output terminal;
first logic configured to generate an output drive signal at the output terminal corresponding to an input drive signal received at the input terminal;
a current sensing terminal;
a reference supply terminal; and
a blanking unit configured to connect the current sense terminal to the reference supply terminal responsive to a low value of the output drive signal and disconnect the current sense terminal from the reference supply terminal after a predetermined delay period responsive to a high value of the output drive signal.

2. The gate driver of claim 1, wherein the blanking unit comprises:
a blanking transistor connected across the current sense terminal and the reference supply terminal; and
a blanking control unit connected to a gate of the blanking transistor and configured to turn on the blanking transistor responsive to a low value of the output drive signal and to turn off the blanking transistor after a predetermined delay period responsive to a high value of the output drive signal.

3. The gate driver of claim 1, wherein the first logic comprises:
control logic connect to the input terminal to receive the input drive signal;
a level shift up unit connected to the control logic and controlled by the control logic to assert a set signal responsive to the input drive signal having a high value and to assert a reset signal responsive to the input drive signal having a low value;
a flip flop coupled to the level shift up unit and configured to generate a pre-drive signal based on value of the set signal and the reset signal; and
a driver connected to the flip flop and configured to generate the output drive signal based on the pre-drive signal.

4. The gate driver of claim 3, comprising:
second logic connected to the current sense terminal configured to generate a clear signal at a clear terminal of the flip flop responsive to a voltage at the current sense terminal exceeding a threshold voltage.

5. The gate driver of claim 4, wherein the second logic comprises:
a comparator connected to the current sense terminal and a voltage source corresponding to the threshold voltage and configured to generate the clear signal responsive to a voltage on the current sense terminal exceeding the threshold voltage;
a noise filter connected to an output of the comparator; and
a pulse generator connected to the noise filter and the clear terminal of the flip flop and configured to generate a clear pulse based on the clear signal.

6. The gate driver of claim 1, comprising:
second logic connected to the current sense terminal configured to generate a disable signal to deassert the output drive signal responsive to a voltage at the current sense terminal exceeding a threshold voltage.

7. The gate driver of claim 6, comprising:
a level shift down unit connected to the second logic to receive the disable signal.

8. A method for generating a gate driver signal, comprising:
receiving an input drive signal at an input terminal of a gate driver;
generating an output drive signal at an output terminal of the gate driver corresponding to the input drive signal;
connecting a current sense terminal of the gate driver to a reference supply terminal of the gate driver responsive to a low value of the output drive signal; and
disconnecting the current sense terminal from the reference supply terminal after a predetermined delay period responsive to a high value of the output drive signal.

9. The method of claim 8, wherein:
connecting the current sense terminal of the gate driver to the reference supply terminal of the gate driver comprises enabling a blanking transistor coupled across the current sensing terminal and the reference supply terminal; and
disconnecting the current sense terminal from the reference supply terminal comprises disabling the blanking transistor.

10. The method of claim 9, wherein generating the output drive signal comprises:
controlling a level shift up unit connected to assert a set signal responsive to the input drive signal having a high value and to assert a reset signal responsive to the input drive signal having a low value;
generating a pre-drive signal based on value of the set signal and the reset signal; and
generating the output drive signal based on the pre-drive signal.

11. The method of claim 10, comprising:
generating a clear signal responsive to a voltage at the current sense terminal exceeding a threshold voltage.

12. The method of claim 11, wherein generating the clear signal comprises:
comparing the threshold voltage to a voltage on the current sense terminal to generate the clear signal;
filtering noise in the clear signal; and
generating a clear pulse based on the clear signal.

13. The method of claim 8, comprising:
generating a disable signal to deassert the output drive signal responsive to a voltage at the current sense terminal exceeding a threshold voltage.

14. The method of claim 13, comprising:
shifting a voltage level of the disable signal from a first voltage level to a second voltage level less than the first voltage level.

15. A gate driver, comprising:
an input terminal;
an output terminal;
a level shift up unit;
control logic configured to generate a set signal in the level shift up unit responsive to an input drive signal having a high value and to generate a reset signal in the level shift up unit responsive to the input drive signal having a low value;
a flip flop coupled to the level shift up unit and configured to generate a pre-drive signal based on value of the set signal and the reset signal;
a driver connected to the flip flop and configured to generate an output drive signal at the output terminal based on the pre-drive signal;
a current sensing terminal;
a reference supply terminal;
a blanking transistor coupled across the current sensing terminal and the reference supply terminal; and
a blanking control unit connected to a gate of the blanking transistor and configured to turn on the blanking transistor responsive to a low value of the pre-drive signal and to turn off the blanking transistor after a predetermined delay period responsive to a high value of the pre-drive signal.

16. The gate driver of claim 15, comprising:
fault detection logic connected to the current sense terminal configured to generate a clear signal at a clear terminal of the flip flop responsive to a voltage at the current sense terminal exceeding a threshold voltage.

17. The gate driver of claim 16, wherein the fault detection logic comprises:
a comparator connected to the current sense terminal and a voltage source corresponding to the threshold voltage and configured to generate the clear signal responsive to a voltage on the current sense terminal exceeding the threshold voltage;
a noise filter connected to an output of the comparator; and
a pulse generator connected to the noise filter and the clear terminal of the flip flop and configured to generate a clear pulse based on the clear signal.

18. The gate driver of claim 15, comprising:
fault detection logic connected to the current sense terminal configured to generate a disable signal to deassert the output drive signal responsive to a voltage at the current sense terminal exceeding a threshold voltage.

19. The gate driver of claim 18, comprising:
a level shift down unit connected to the fault detection logic to receive the disable signal.

20. The gate driver of claim 19, comprising:
a first fault indication terminal;
a second fault indication terminal;
a fault indication transistor coupled across the first fault indication terminal and the second fault indication terminal and having a gate terminal connected to the level shift down unit; and
a capacitor coupled across the first fault indication terminal and the second fault indication terminal.
